(19) United States
(12) Patent Application Publication
(10) Pub. No.: US 2014/0283748 A1
(43) Pub. Date: Sep. 25, 2014

(54) SEMICONDUCTOR MANUFACTURING APPARATUS AND SEMICONDUCTOR WAFER HOLDER

(71) Applicant: KABUSHIKI KAISHA TOSHIBA, Minato-ku (JP)

(72) Inventors: Shinya Higashi, Kanagawa-ken (JP); Shinya Sato, Hyogo-ken (JP); Tomoyuki Sakuma, Hyogo-ken (JP); Akihiko Osawa, Hyogo-ken (JP); Hiroaki Kobayashi, Kanagawa-ken (JP); Osamu Yamazaki, Kanagawa-ken (JP); Hiroshi Nishimura, Kanagawa-ken (JP)

(73) Assignee: KABUSHIKI KAISHA TOSHIBA, Minato-ku (JP)

(21) Appl. No.: 14/024,357

(22) Filed: Sep. 11, 2013

(30) Foreign Application Priority Data
Mar. 22, 2013 (JP) 2013-061133

(51) Int. Cl. C30B 25/12

(52) U.S. Cl. CPC C30B 25/12
USPC 118/725; 118/730

(57) ABSTRACT

A semiconductor manufacturing apparatus includes a chamber, a reaction-gas inlet, a gas exhaust port, a rotation unit, a semiconductor wafer holder, a heater, and a purge-gas inlet. The wafer holder includes a first hold region to hold the semiconductor wafer and a second hold region held by the rotation unit. The second hold region surrounds the first hold region. The level of the first hold region and the level of the second hold region differ. A plurality of ventholes is provided to the first hold region so that the ventholes are just below a sidewall of the semiconductor wafer held by the first hold region.

### CROSS REFERENCE TO RELATED APPLICATION

This application is based upon and claims the benefit of priority from the prior Japanese Patent Application No. 2013-061133, filed on Mar. 22, 2013, the entire contents of which are incorporated herein by reference.

### FIELD

Embodiments described herein generally relate to a semiconductor manufacturing apparatus and a semiconductor wafer holder.

### BACKGROUND

An epitaxial growth method enables a crystal film to grow from a vapor phase on substrates including a semiconductor wafer. A semiconductor manufacturing apparatus using the epitaxial growth method includes a chamber and a rotation unit inside the chamber. A semiconductor wafer holder is provided over the upper surface of the rotation unit, and a heater to heat a semiconductor wafer is provided under the semiconductor wafer holder.

A source gas is introduced into the chamber to grow a crystal film on the semiconductor wafer while the semiconductor wafer is rotated with the rotation unit.

Power semiconductor devices including an IGBT device need a silicon epitaxial film that is about 10 μm in thickness. A silicon wafer is held by a holder, and a single crystal semiconductor film grows on the surface of the silicon wafer by thermal decomposition reaction of a source gas. Rotating the semiconductor wafer at high speeds enhances the supply of the source gas to the semiconductor wafer and the reaction of the source gas.

In contrast, increasing the rotation speed misaligns the center of the silicon wafer and the center of the holder to thereby make the outer edge of the wafer in contact with the inner sidewall of the holder. The source gas penetrates a clearance between the silicon wafer and the holder to cause film growth at sites of the contact between the semiconductor wafer and the holder.

Growing a thick silicon epitaxial film can cause the silicon wafer and the holder to adhere to each other in some cases. In such cases, taking out the silicon wafer with the thick film from the chamber causes crystal defects to occur in the thick epitaxial film, or causes cracks to occur in the silicon wafer and the holder.

### BRIEF DESCRIPTION OF THE DRAWINGS

The accompanying drawings, which are incorporated in and constitute a part of this specification, illustrate embodiments of the invention and together with the description, serve to explain the principles of the invention.

FIG. 1 is a schematic diagram showing a semiconductor manufacturing apparatus according to a first embodiment.

FIG. 2A is a schematic plan view showing a semiconductor wafer holder according to the first embodiment.

FIG. 2B is a sectional view schematically showing the semiconductor wafer holder according to the first embodiment.

FIG. 3A is a sectional view showing a result obtained with a semiconductor manufacturing apparatus according to a reference example.

FIG. 3B is a sectional view showing a result obtained with the semiconductor manufacturing apparatus according to the first embodiment.

FIG. 4A is a schematic plan view showing a semiconductor wafer holder according to a second embodiment.

FIG. 4B is an enlarged view of the schematic plan view, showing the semiconductor wafer holder according to the second embodiment.

FIG. 4C is a schematic cross-sectional view showing the semiconductor wafer holder according to the second embodiment.

FIG. 5A is a schematic plan view showing a semiconductor wafer holder according to a third embodiment.

FIG. 5B is an enlarged view of the plan view showing the semiconductor wafer holder according to the third embodiment.

FIG. 5C is a schematic cross-sectional view showing the semiconductor wafer holder according to the third embodiment.

FIG. 6A is a schematic plan view showing a semiconductor wafer holder according to a fourth embodiment.

FIG. 6B is an enlarged view of the schematic plan view showing the semiconductor wafer holder according to the fourth embodiment.

FIG. 7A is a schematic cubic diagram showing a semiconductor wafer holder according to a fifth embodiment.

FIG. 7B is a schematic cross-sectional view showing the semiconductor wafer holder according to the fifth embodiment.

FIG. 8A is a schematic plan view showing a semiconductor wafer holder according to a sixth embodiment.

FIG. 8B is a schematic sectional view showing the semiconductor wafer holder according to the sixth embodiment.

FIG. 9 is a schematic plan view showing a semiconductor wafer holder according to a seventh embodiment.

FIGS. 10A and 10B are diagrams showing effects of the semiconductor wafer holders.

FIG. 11 is a schematic diagram showing effects of the semiconductor wafer holders.

FIG. 12 is a schematic diagram showing effects of the semiconductor wafer holders.

### DETAILED DESCRIPTION

According to an embodiment, a semiconductor manufacturing apparatus includes a chamber, a reaction-gas inlet, a gas exhaust port, a rotation unit, a semiconductor wafer holder, a heater, and a purge-gas inlet. The reaction-gas inlet is provided to the chamber to introduce a reaction gas into the chamber. The gas exhaust port is provided to the chamber to exhaust the reaction gas. The rotation unit is provided to the chamber. The semiconductor wafer holder is provided above the rotation unit to hold a semiconductor wafer. The heater is provided inside the rotation unit. The purge-gas inlet introduces a purge gas into a space. The space is enclosed by the rotation unit, the semiconductor wafer holder and the semiconductor wafer.

The semiconductor wafer holder includes a first hold region and a second hold region. The first hold region holds the semiconductor wafer. The second hold region is held by the rotation unit and surrounds the first hold region. The level of the first hold region and the level of the second hold region differ. The ventholes are provided to the first hold region so that the ventholes are just below a sidewall of the semiconductor wafer held by the first hold region.

Embodiments will be described with reference to the drawings. Wherever possible, the same reference numerals or marks denote the same or like portions throughout the drawings. Detailed description about the same will not be repeated.

### First Embodiment

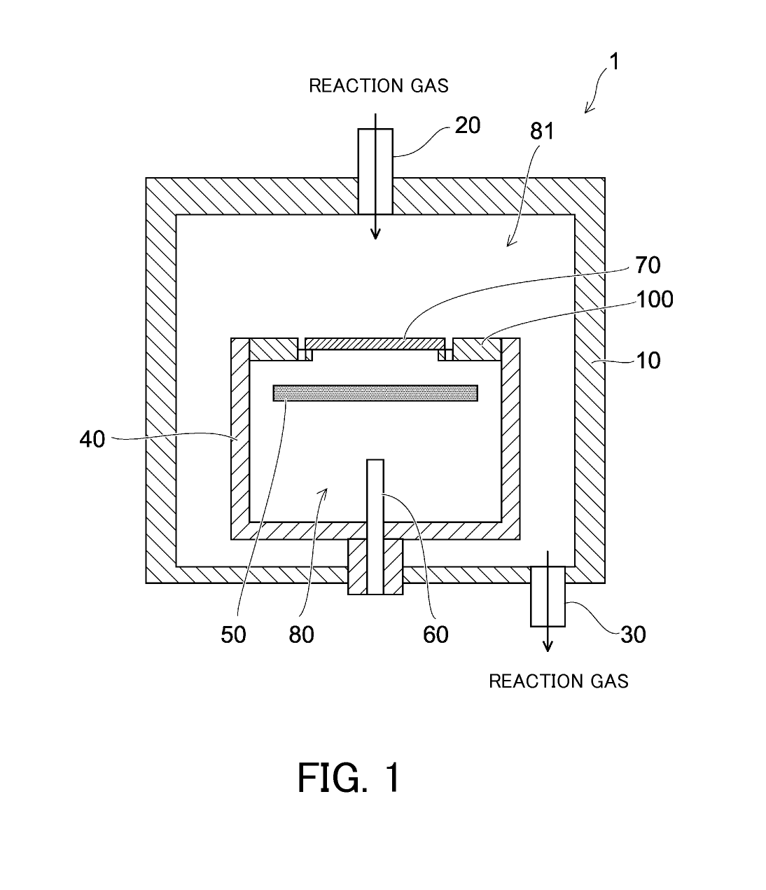

FIG. 1 is a schematic diagram showing a semiconductor manufacturing apparatus in accordance with a first embodiment.

A semiconductor manufacturing apparatus 1 in accordance with the first embodiment is to epitaxially grow a semiconductor layer over a semiconductor wafer. The semiconductor manufacturing apparatus 1 includes a chamber 10, a reaction-gas inlet 20, a gas exhaust port 30, a rotation unit 40, a semiconductor wafer holder 100, a heater 100, and a purge-gas inlet 60.

The reaction gas inlet 20 is provided to the chamber 10. A source gas is introduced into the chamber 10 from the reaction-gas inlet 20. The gas exhaust port 30 is provided to the chamber 10. The reaction gas is exhausted from the gas exhaust port 30.

The rotation unit 40 is provided inside the chamber 10. The semiconductor wafer holder 100 is provided over the upper side of the rotation unit 40. A semiconductor wafer 70, e.g., a silicon wafer, is held by the semiconductor wafer holder 100.

The rotation unit 40 rotates about a rotation axis of the rotation unit 40 to rotate the semiconductor wafer holder 100 held by the rotation unit 40 and the semiconductor wafer 70 held by the semiconductor wafer holder 100. The rotation unit 40 is capable of rotating at 5000 rpm or more. In the embodiment, a counterclockwise direction is referred to as a rotation direction, and a clockwise direction is referred to as an anti-rotation direction. Alternatively, the counterclockwise direction may be referred to as the anti-rotation direction, and the clockwise direction may be referred to as the rotation direction.

The heater 50 is provided inside the rotation unit 40. When the underside of the semiconductor wafer 70 is heated by the heater 50, heat from the heater 50 is conducted from the underside to the top side of the semiconductor wafer 70. As a result, the top surface of the semiconductor wafer 70 is heated. The surface temperature Ts of the semiconductor wafer 70 is set to 500° C. to 2000° C., for example.

The chamber 10 includes the purge gas inlet 60. A purge gas is supplied through the purge gas inlet 60 to a space 80 enclosed by the rotation unit 40, the semiconductor holder 100, and the semiconductor wafer 70. A process space 81 is defined to be a space that is outside the space 80 and enclosed by the chamber 10.

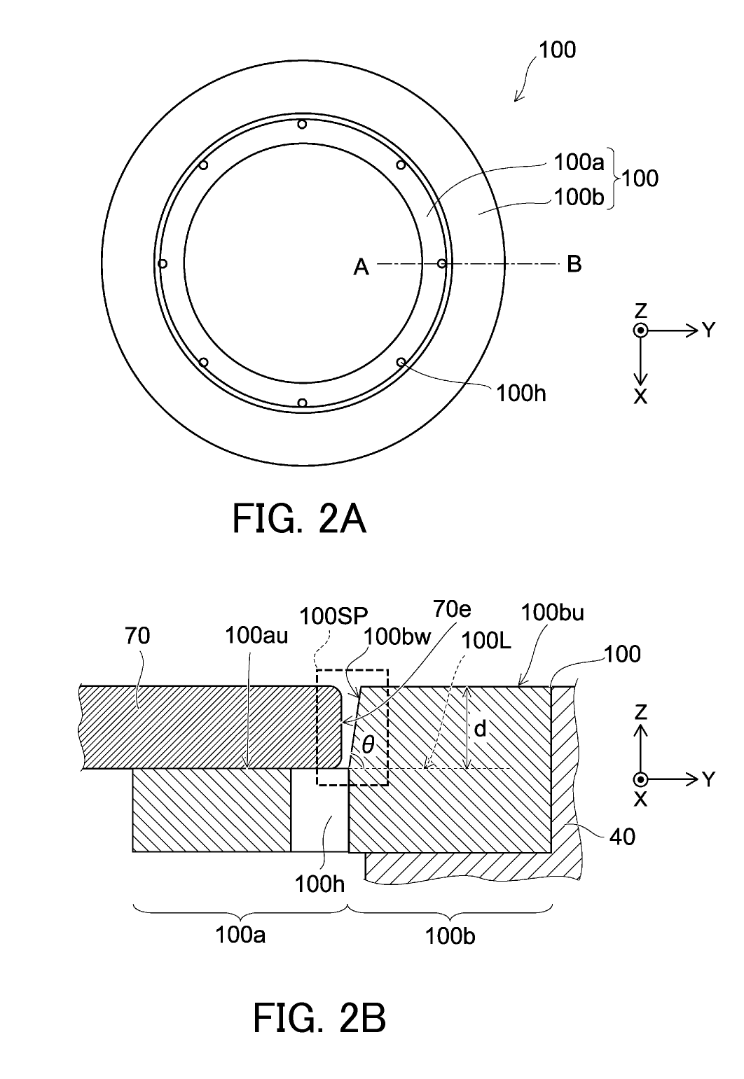

The semiconductor wafer holder 100 will be described in detail. FIG. 2A is a schematic plan view showing a semiconductor wafer holder in accordance with the first embodiment, and FIG. 2B is a sectional view schematically showing the semiconductor wafer holder.

FIG. 2B shows a cross-section taken along the line A-B in FIG. 2A. FIG. 2B also shows a portion of a semiconductor wafer 70 and a portion of the rotation unit 40 in addition to the semiconductor wafer holder 100.

A three-dimensional coordinate is used in FIGS. 2A and 2B. The X-axis or the Y-axis is assigned to a direction parallel to the semiconductor wafer holder 100, and the Z-axis is assigned to a direction perpendicular to the surface of the semiconductor wafer holder 100. In the embodiment, an X-Y plane is defined by the X-axis and the Y-axis, and is referred to simply as a “plane.” A positive direction of the Z-axis is referred to as an “upward direction,” and a negative direction of the Z-axis is referred to as a “downward direction.” A shape on the “X-Y plane” or on the “plane” is referred to as a “planar shape.”

The semiconductor wafer holder 100 includes a first hold region 100a holding the semiconductor wafer 70 and a second hold region 100b held by the rotation unit 40. The first hold region 100a is surrounded by the second hold region 100b. The planar shape of the first hold region 100a is ring-like. The ring-like first hold region 100a holds an outer circumference of the semiconductor wafer 70. Materials of the semiconductor wafer holder 100 include silicon carbide (SiC), ceramics, and carbon (C).

The semiconductor wafer holder 100 has a difference 100sp between levels of the first and second hold regions 100a, 100b. The difference 100sp structurally includes an upper surface 100au of the first hold region 100a, an upper surface 100bu of the second hold region 100b, and an inside surface 100bw of the second hold region 100b. The inside surface 100bw is near the two upper surfaces 100au and 100bu.

The semiconductor wafer holder 100 is made by drilling a material block prepared for the semiconductor wafer holder 100 such that the first hold region 100a has a larger diameter than the semiconductor wafer 70. A depth d of the drilled region of the material block is suitably adjusted. In FIG. 2B, the depth d is exemplified as to be approximately equal to the thickness of the semiconductor wafer 70. The depth d may be suitably changed. An inside surface 100bw of the second hold region 100b forms a slope. An extended line 100L and the inside surface 100bw makes an angle of 90° or less. The extended line 100L is extended from an upper surface 100au of the first hold region 100b to the side of the second hold region 100b. Such a slope, i.e., the inside surface 100bw, makes it easy to place the semiconductor wafer 70 on the first hold region 100a from above the semiconductor wafer holder 100. Placing the semiconductor wafer 70 on the first hold region 100a causes a sidewall 70e of the semiconductor wafer 70 to face the inside surface 100bw.

The first hold region 100a includes a plurality of ventholes 100h located just below the sidewall 70e when the semiconductor wafer 70 is placed on the first hold region 100a. The ventholes 100h allows a purge gas to be vented from the space 80. The ventholes 100h are through-holes to pass through the semiconductor wafer holder 100 in the Z-direction.

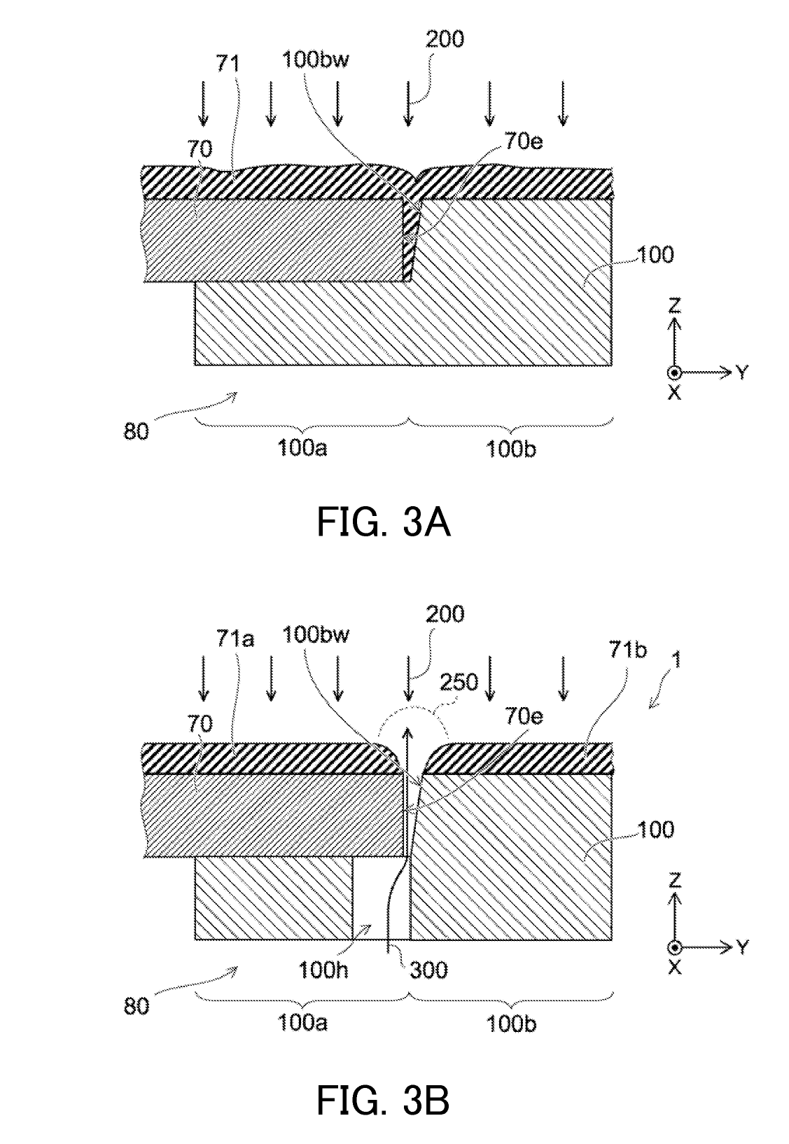

Operation of the semiconductor manufacturing apparatus 1 will be described below. FIG. 3A is a sectional view showing a result obtained with a semiconductor manufacturing apparatus in accordance with a reference example. FIG. 3B is a sectional view showing a result obtained with the semiconductor manufacturing apparatus in accordance with the first embodiment.

As shown in FIG. 3A, a semiconductor wafer holder 100 without a venthole is assumed.

Using such a wafer holder 100 without a venthole, an epitaxial film 71 is formed on the semiconductor wafer 70 by introducing a source gas, such as SiH₂Cl₂, from the reaction-gas inlet 20 while the semiconductor wafer 70 is rotated by the rotation unit 40.

The semiconductor wafer 70 is rotated at a high rotation speed. The high-speed rotation generates a centrifugal force applied to the semiconductor wafer 70 during the growth, thereby misaligning the center of the semiconductor wafer 70 and the center of the rotation unit 40. The centrifugal force causes the semiconductor wafer 70 to be near or in contact with the inside surface 100bw. The source gas 200 penetrates a clearance between the semiconductor wafer 70 and the semiconductor wafer holder 100 without a venthole.

Continuing the growth under such a condition causes the epitaxial film 71 to grow on the respective upper surfaces of the semiconductor wafer 70 and the semiconductor wafer holder 100 without a venthole and to fill the clearance between the semiconductor wafer 70 and the semiconductor wafer holder 100 without a venthole.

The thicker the epitaxial film 71 is, more strongly the semiconductor wafer 70 adheres to the semiconductor wafer holder 100 without a venthole through the epitaxial film 71 grown to fill the clearance.

After the epitaxial growth on the semiconductor wafer 70 is completed, the semiconductor wafer 70 is detached from the semiconductor wafer holder 100 without a venthole. At that time, the epitaxial film 71 having filled the clearance prevents the semiconductor wafer 70 from being smoothly detached from the semiconductor wafer holder 100 without a venthole.

Such an undesirable epitaxial film 71 having filled the clearance can form defects in the epitaxial film 71 on the semiconductor wafer 70 in some cases. In a severe case, the semiconductor wafer holder 100 without a venthole or the semiconductor wafer 70 can be chipped.

In contrast, the semiconductor wafer holder 100 of the first embodiment includes the ventholes. Using the wafer holder 100 of the first embodiment, an epitaxial film 71 is formed on the semiconductor wafer 70 by introducing a source gas 200, such as SiH₂Cl₂, through the reaction-gas inlet 20 while the semiconductor wafer 70 is rotated with the rotation unit 40. High-speed rotation of the semiconductor wafer 70 generates centrifugal force applied to the semiconductor wafer 70 during the growth, thereby causing the semiconductor wafer 70 to be near or in contact with the inside surface 100bw of the second hold region 100b.

In the first embodiment, purge gas 300, such as hydrogen (H₂), is introduced from the purge gas inlet 60 while the source gas 200 is introduced from the reaction-gas inlet 20. The pressure of the space 80 is set higher than the pressure outside the space 80. This situation allows the purge gas 300 to flow out from the space 80 to the process space 81 through the ventholes 100h and a clearance between the semiconductor wafer 70 and the semiconductor wafer holder 100. As a result, a boundary 250 between the source gas 200 and the purge gas 300 is formed above the sidewall 70e of the semiconductor wafer 70. As shown in FIG. 3B, the source gas 200 is diluted with the purge gas 300 under the boundary 250, i.e., around the sidewall 70e.

The dilution of the source gas 200 prevents an epitaxial film 71 from growing around on the sidewall 70e of the semiconductor wafer 70. The outflow of the purge gas 300 prevents the source gas 200 from flowing into the clearance between the semiconductor wafer 70 and the semiconductor wafer holder 100. As a result, the epitaxial film 71 is grown on each of the upper surfaces of the semiconductor wafer 70 and the semiconductor wafer holder 100.

Thus, the epitaxial film 71 on the semiconductor wafer 70 is not chipped or damaged by an undesirable epitaxial film 71 grown on any portions other than the semiconductor wafer 70 when the semiconductor wafer 70 is detached from the semiconductor wafer holder 100. This prevents the epitaxial film 71 on the semiconductor wafer 70 from containing defects. In addition, the semiconductor wafer holder 100 or the semiconductor wafer 70 is not easily chipped. Using the semiconductor wafer holder 100 enhances productivity of manufacturing semiconductors. As described above, hydrogen is used as the purge gas 300 in the first embodiment. Alternatively, inactive gas may be used as the purge gas 300 in the first embodiment. Using argon (Ar) with high molecular weight for the purge gas 300 enables it to prevent the source gas 200 from flowing into a clearance between the semiconductor wafer 70 and the semiconductor wafer holder 100 more effectively than using hydrogen. Ar also reduces the source gas 200 from diffusing into the clearance to thereby prevent films from undesirably growing near the heater 50 and parts of the heater 50 from wearing.

### Second Embodiment

As described above, the semiconductor wafer 70 is rotated at a high rotation speed with the rotation unit 40. The centrifugal force due to the high-speed rotation misaligns the centers of the semiconductor wafer 70 and the rotation unit 40 during deposition.

When the misalignment causes the semiconductor wafer 70 to be near or in contact with the inside surface 100bw and when one venthole 100h is located just below an approach point or a contact point between the semiconductor wafer 70 and the semiconductor wafer holder 100, the gas purge through the venthole 100h prevents film growth at the approach point or the contact point between the semiconductor wafer 70 and the semiconductor wafer holder 100 in the first embodiment.

In the first embodiment, therefore, it's preferred that one of the ventholes 100h is located just below the approach point or the contact point between the semiconductor wafer 70 and the semiconductor wafer holder 100 for every deposition in order to prevent the above-mentioned undesirable film growth at the clearance therebetween.

Unfortunately, an increase in the number of the ventholes 100h to be provided to the semiconductor wafer holder 100 leads to an increase in cost of manufacturing a semiconductor wafer holder. The more ventholes 100h are provided, the lower the mechanical strength of connection between the first hold region 100a and the second hold region 100b is.

In a second embodiment, protrusions are provided to a semiconductor wafer holder as to enable it to precisely position the semiconductor wafer 70 on the semiconductor wafer holder. The ventholes are provided one by one just below each of the protrusions.

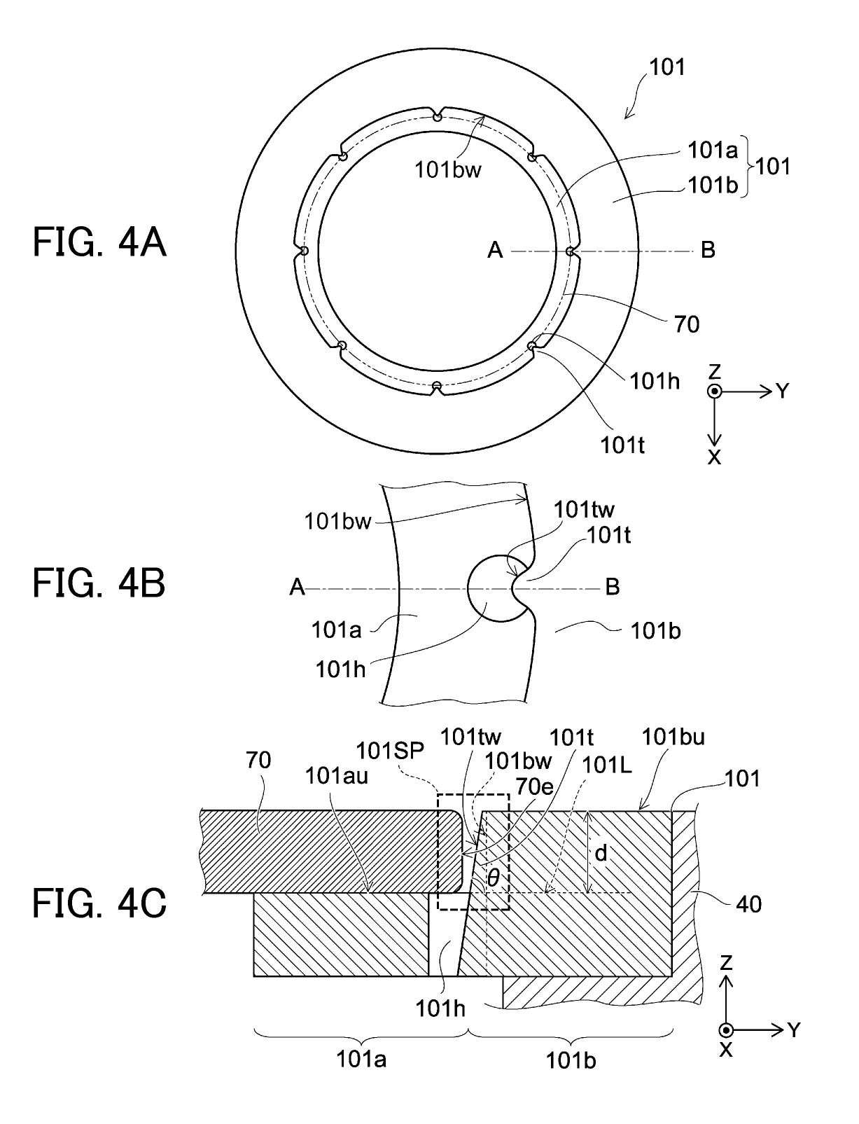

FIG. 4A is a schematic plan view showing a semiconductor wafer holder in accordance with the second embodiment. FIG. 4B is an enlarged view of the schematic plan view, showing the semiconductor wafer holder in accordance with the second embodiment. FIG. 4C is a schematic cross-sectional view showing the semiconductor wafer holder in accordance with the second embodiment. FIG. 4C shows a cross-section taken along the line A-B in FIG. 4A.

A semiconductor wafer holder 101 includes a first hold region 101a holding the semiconductor wafer 70 and a second hold region 101b held by the rotation unit 40. The first hold region 101a is surrounded by the second hold region 101b. A planar shape of the first hold region 101a is ring-like. The ring-like first hold region 101a holds an outer circumference of the semiconductor wafer 70. Materials of the semiconductor wafer holder 101 include silicon carbide (SiC), ceramics, and carbon (C).

The semiconductor wafer holder 101 has a difference 101sp between levels of the first and second hold regions 101a and 101b. The difference 101sp structurally includes an upper surface 101au of the first hold region 100a, an upper surface 101bu of the second hold region 100b, and an inside surface 101bw of the second hold region 100b. The inside surface 101bw is near the two upper surfaces 101au and 101bu.

The semiconductor wafer holder 101 is made by drilling a material block prepared for the semiconductor wafer holder 101 such that the first hold region 101a has a larger diameter than the semiconductor wafer 70. A depth d of the drilled region of the material block is suitably adjusted. In FIG. 4C, the depth d is exemplified as to be approximately equal to the thickness of the semiconductor wafer 70. The depth d may be suitably changed.

The inside surface 101bw of the second hold region 100b forms a slope. A protrusion 101t protrudes toward the semiconductor wafer 70 from the inside surface 101bw. An inside surface 101tw of the protrusion 101t forms a slope. An extended line 101L and the inside surface 100tw makes an angle of 90° or less. The extended line 101L is extended from the upper surface 101au to the side of the second hold region 101b. The protrusion 101t is at the outer outside of the sidewall 70e of the semiconductor wafer 70. The protrusion 101t allows it to easily place the semiconductor wafer 70 onto the first hold region 101a from above the semiconductor wafer holder 100.

Placing the semiconductor wafer 70 onto the first hold region 101a causes the sidewall 70e of the semiconductor wafer 70 to face the inside surface 100tw of the protrusion 101t. Placing the semiconductor wafer 70 onto the first hold region 101a causes the protrusions 101t to automatically position the semiconductor wafer 70 in the first hold region 101a.

The first hold region 101a includes a plurality of ventholes 101h located just below the sidewall 70e when the semiconductor wafer 70 is placed on the first hold region 101a. The ventholes 101h enables a purge gas to be vented from the space 80.

A protrusion 101t is provided above each of the ventholes 101h. The protrusion 101t protrudes from the inside surface 101bw of the second hold region 101b toward the first hold region 101a.

An epitaxial film 71 is formed on the semiconductor wafer 70 by using the semiconductor wafer holder 101. For example, an epitaxial film 71 is formed on the semiconductor wafer 70 by introducing a source gas, such as SiH₂Cl₂, from the reaction-gas inlet 20 while the semiconductor wafer 70 is rotated with the rotation unit 40.

High-speed rotation of the semiconductor wafer 70 generates centrifugal force to the semiconductor wafer 70 during the growth, thereby causing the semiconductor wafer 70 to be near or in contact with the inside surfaces 101tw of the protrusions 101t. The semiconductor wafer holder 101 allows the semiconductor wafer 70 to be near the inside surfaces 101tw of the protrusions 101t and the ventholes 101h to be surely located just below the protrusions 101t.

In the second embodiment, the source gas 200 is introduced from the reactive gas inlet 20, and the purge gas 300, such as hydrogen (H₂) and argon (Ar), is introduced into the rotation unit 40 from the purge-gas inlet 60. The pressure inside the space 80 is set higher than the pressure outside the space 80. This allows the purge gas 300 to flow from the space 80 to the process space 81 by way of the ventholes 101h and through the clearance between the semiconductor wafer 70 and the semiconductor wafer holder 101. As a result, a boundary between the source gas 200 and the purge gas 300 is formed over the sidewall 70e of the semiconductor wafer 70 (as well as in FIG. 3B). The source gas 200 is diluted with the purge gas 300 under the boundary 250, i.e., around the sidewall 70e.

The dilution of the source gas 200 prevents an epitaxial film 71 from growing around the sidewall 70e of the semiconductor wafer 70. The outflow of the purge gas 300 prevents the source gas 200 from flowing into the clearance between the semiconductor wafer 70 and the semiconductor wafer holder 101. As a result, an epitaxial film 71 is grown on each of the upper surfaces of the semiconductor wafer 70 and the semiconductor wafer holder 101.

Thus, the epitaxial film 71 on the semiconductor wafer 70 is not chipped or damaged by an undesirable epitaxial film 71 grown on any portions other than the semiconductor wafer 70 when the semiconductor wafer 70 is detached from the semiconductor wafer holder 101. This prevents the epitaxial film 71 on the semiconductor wafer 70 from containing defects. In addition, the semiconductor wafer holder 101 or the semiconductor wafer 70 is not easily chipped. The use of the semiconductor wafer holder 101 enhances productivity of manufacturing semiconductors.

The protrusions 101t operates as support portions to position the semiconductor wafer 70. Thus, the protrusions 101t located around the semiconductor wafer 70 prevent misalignment due to the high-speed rotation of the semiconductor wafer 70. At least 3 protrusions 101t may be provided at regular intervals of 120°, thereby enabling it to fix the sidewall 70e of the semiconductor wafer 70 with the 3 protrusions 101t. In that case, 3 ventholes 101h correspond in one-to-one to the 3 protrusions 101t.

So many ventholes are not necessarily provided. A few ventholes will not bring about an increase in cost of manufacturing a semiconductor wafer holder. The mechanical strength of connection between the first hold region 100a and the second hold region 100b will not lower.

### Third Embodiment

A venthole may be cutout-shaped in addition to the through-hole shaped as mentioned above.

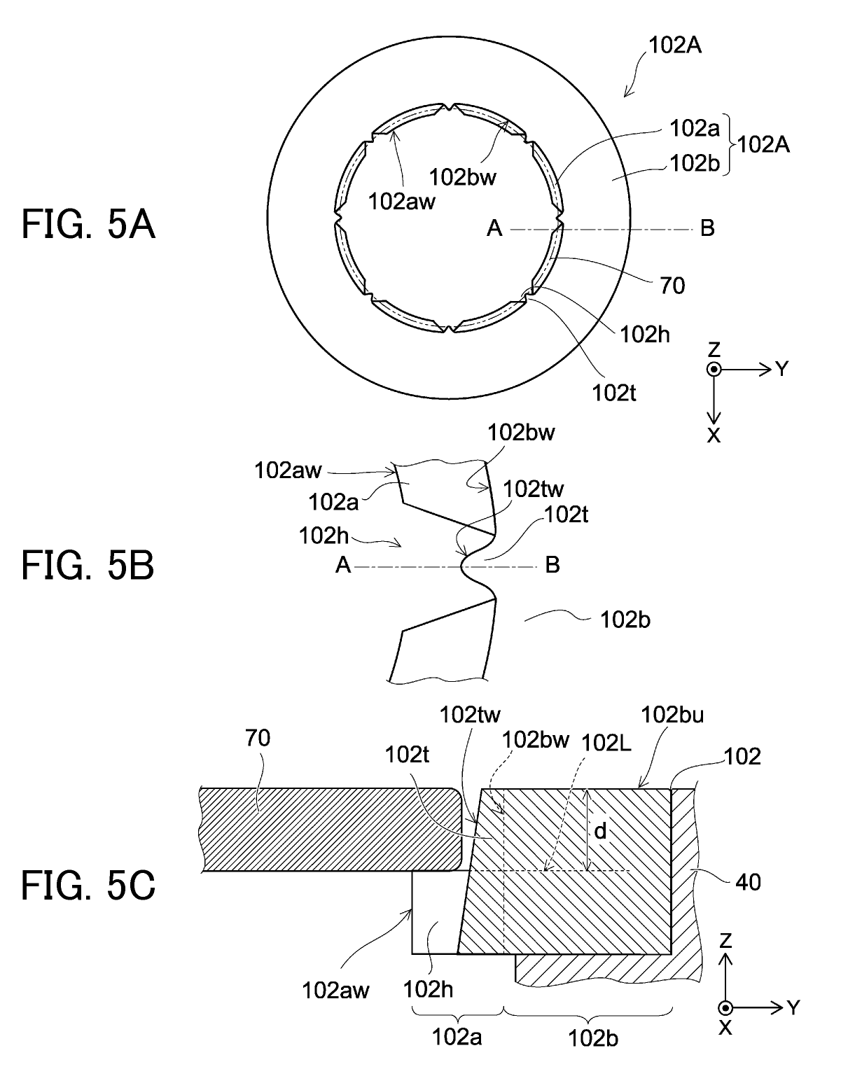

FIG. 5A is a schematic plan view showing a semiconductor wafer holder in accordance with a third embodiment. FIG. 5B is an enlarged view of the plan view. FIG. 5C is a schematic cross-sectional view showing the semiconductor wafer holder. FIG. 5C shows a cross-section taken along the line A-B in FIG. 5A.

A semiconductor wafer holder 102A includes a first hold region 100a holding a semiconductor wafer 70 and a second hold region 100b held by a rotation unit 40. The first hold region 102a is surrounded by the second hold region 102b. The planar shape of the first hold region 102a is ring-like. The ring-like first hold region 102a holds an outer circumference of the semiconductor wafer 70. Materials of the semiconductor wafer holder 100 include silicon carbide (SiC), ceramics, and carbon (C).

The semiconductor wafer holder 102A is made by drilling a material block prepared for the semiconductor wafer holder 102A such that the first hold region 102a has a larger diameter than the semiconductor wafer 70. A depth d of the drilled region of the material block is suitably adjusted. In FIG. 5C, the depth d is exemplified as to be approximately equal to the thickness of the semiconductor wafer 70. The depth d may be suitably changed.

The inside surface 102bw of the second hold region 102bw forms a slope. The second hold region 102b includes the protrusions 102t having the same structure as that of the protrusion 101t.

Placing the semiconductor wafer 70 on the first hold region 102a allows the sidewall 70e of the semiconductor wafer 70 to face the inside surface 102tw. Placing the semiconductor wafer 70 onto the first hold region 102a allows the protrusions 102t to automatically position the semiconductor wafer 70 in the first hold region 102a.

The first hold region 102a includes a plurality of ventholes 102h located just below the sidewall 70e when the semiconductor wafer 70 is placed on the first hold region 102a. The ventholes 102h enables a purge gas to be vented from the space 80. The venthole 102h in accordance with the third embodiment is a cutout that is cut out from the inner circumference toward the outer circumference of the ring-shaped first hold region 102a. For example, the cutout is provided from the inside surface 102aw of the first hold region 102a toward the second hold region 102b.

The protrusion 102t is provided above the ventholes 102h as to protrude into each of the ventholes 102 h. The protrusion 102t protrudes from the inside surface 102bw of the second hold region 102b toward the first hold region 102a.

Such ventholes 102h also allows a purge gas 300 to flow from the space 80 to the process space 81 through the ventholes 102h and a space between the semiconductor wafer 70 and the semiconductor wafer holder 102A. As a result, a boundary between a source gas 200 and the purge gas 300 is formed above the sidewall 70e of the semiconductor wafer 70 (as well as in FIG. 3B). The source gas 200 is diluted with the purge gas 300 under the boundary, i.e., around the sidewall 70e.

The dilution of the source gas 200 prevents an epitaxial film 71 from growing around on the sidewall 70e of the semiconductor wafer 70. The outflow of the purge gas 300 prevents the source gas 200 from flowing into a clearance between the semiconductor wafer 70 and the semiconductor wafer holder 102A. As a result, an epitaxial film 71 grows on each of the upper surfaces of the semiconductor wafer 70 and the semiconductor wafer holder 102A. The use of the semiconductor wafer holder 102A enhances productivity of manufacturing semiconductors.

In some cases, thermal stress can be caused near the ventholes of the semiconductor wafer holder 102A. Temperature differences involved in heating or cooling of the semiconductor wafer 70 causes thermal stress. The venthole 102h of a cutout type differs from the venthole 101h of a through-hole type in that a portion of a side surface of the venthole 102h is open toward the center of the semiconductor wafer holder 102A. The cutout-shaped venthole 102h of the semiconductor wafer holder 102A relaxes the thermal stress around the venthole 102h. Thus, the semiconductor wafer holder 102A has higher tolerance against thermal stress and a structure that breaks down less easily.

### Fourth Embodiment

The planar shape of the venthole with a protrusion is not necessarily symmetric with respect to the center of the protrusion. The planar shape may be unsymmetrical to the center line of the protrusion.

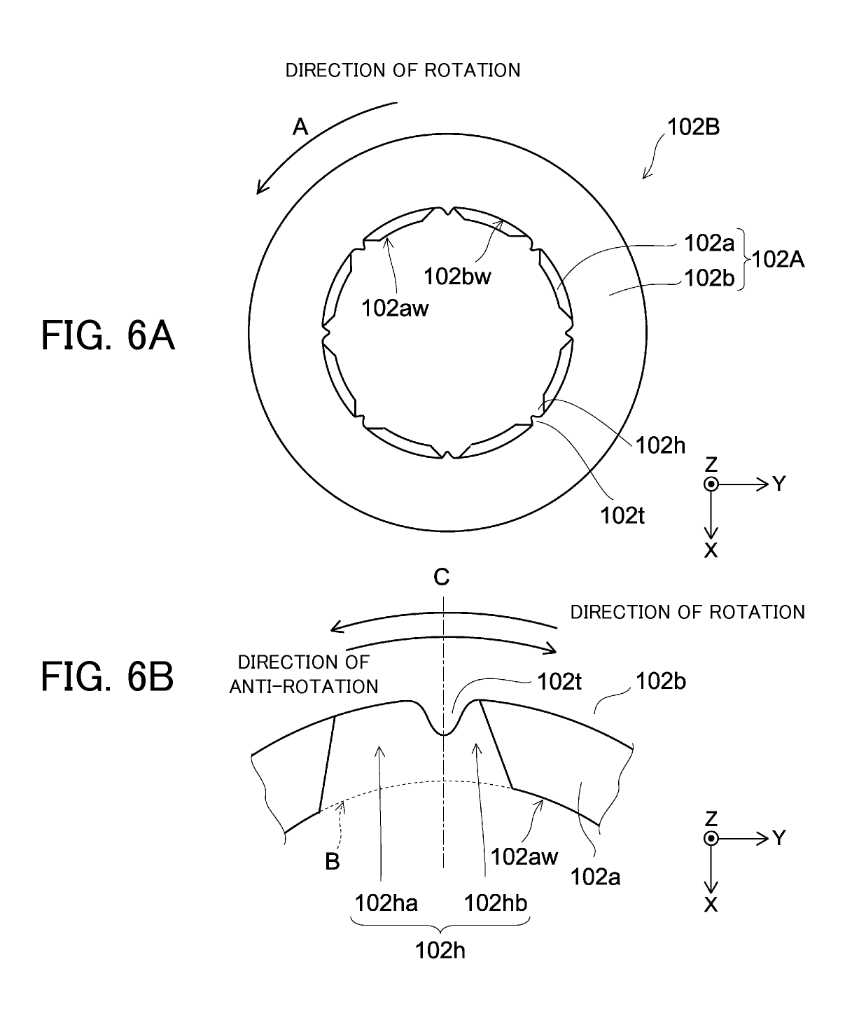

FIG. 6A is a schematic plan view showing a semiconductor wafer holder in accordance with a fourth embodiment. FIG. 6B is an enlarged view of the schematic plan view.

As shown in FIG. 6B, a venthole 102h is divided into a venthole 102ha and a venthole 102hb regarding the planar shape of the venthole 102h. The ventholes 102ha and 102hb are assigned to a rotation direction and an anti-rotation direction (shown in FIG. 6A) with respect to a center line C of the protrusion 102t, respectively. The center line C is denoted by a dashed line.

The planar shape (the opening shape) of the venthole 102h of the fourth embodiment is unsymmetrical with respect to the center line C of the protrusion 102t. The venthole 102ha has a larger planar shape than the venthole 102hb.

A planar area (a opening area) of a cutout-shaped venthole is defined as follows. As shown in FIG. 6B, the planar area of the venthole 102h is defined as an area surrounded by a curve B, the first hold regions 102a, and the second hold region 102b in the X-Y plane. The curve B has the same curvature as the curvature of the inside surface 102aw of the first hold region 102a.

In the fourth embodiment, the planar area of the venthole 102ha is larger than the planar area of the venthole 102hb. The ventholes 102ha and 102hb are assigned to the counterclockwise direction and the clockwise direction with respect to the center line C, respectively. The planar area of the venthole 102h consists of the planar areas of the ventholes 102ha and 102hb. The planar area of the venthole 102ha becomes larger than the planar area of the venthole 102hb in the rotation direction.

When the semiconductor wafer holder 102B rotates, the venthole 102h has the venthole 102ha with the larger planar area before the protrusion 102t in the rotation direction. Thus, the rotation of the semiconductor wafer holder 102B allows a purge gas to flow out of the venthole 102ha having the larger planar area and to subsequently ascend the protrusion 102t. The semiconductor wafer holder 102B in accordance with the fourth embodiment enables the purge gas to ascend the protrusions 102t and to thereby flow out above the protrusions 102t. Thus, the source gas 200 is diluted more efficiently above the protrusions 102t. The dilution prevents an epitaxial film 71 from growing around on the sidewall 70e of the semiconductor wafer 70.

FIGS. 6A and 6B exemplify the venthole 102h of a cutout type. The ventholes 100h and 101h, both being of a through-hole type, may have unsymmetrical planar shapes.

### Fifth Embodiment

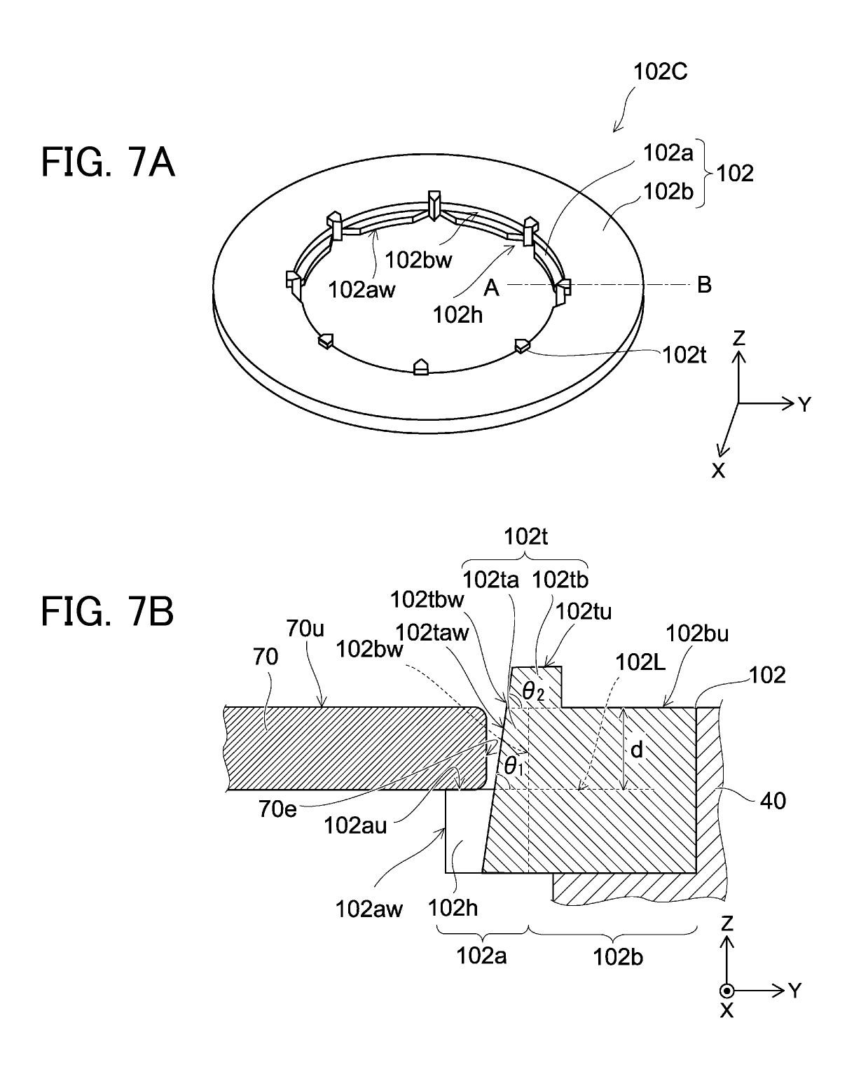

FIG. 7A is a schematic cubic diagram showing a semiconductor wafer holder in accordance with a fifth embodiment. FIG. 7B is a schematic cross-sectional view showing the semiconductor wafer holder in accordance with the fifth embodiment.

FIG. 7B shows a cross-section taken along the line A-B in FIG. 7A.

In the fifth embodiment, a level of an upper end 102tu of the protrusion 102t is higher than the level of an upper end 102bu of the second hold region 102b. The protrusion 102t includes a protrusion 102ta and a protrusion 102tb. The protrusion 102ta protrudes from the inside surface 102bw of the second hold region 102b. The protrusion 102tb is provided on the protrusion 102ta. The protrusion 102tb may be provided above the protrusion 102ta.

In the fifth embodiment, an extended line and an inside surface 102taw make an angle θ1 of 90° or less. The extended line is extended from the upper surface 102au toward the second hold region 102b.

Alternatively, an angle θ2, which an upper surface 102bu of the second hold region 102b and an inside surface 102tbw of the protrusion 102tb make, may be equal to or different from the angle θ1. For example, the angle θ2 may be 90° or more. Specifically, the angle θ2 may be larger than the angle θ1. Setting the angle θ2 larger than the angle θ1 prevents the semiconductor wafer 70 from sliding on the protrusion 102ta to fly away from the semiconductor wafer holder 102C, provided that the respective protrusions 102ta and 102tb are located outside the sidewall 70 of the semiconductor wafer 70.

When the semiconductor wafer holder 102C has such a structure, where the protrusion 102t extends above the upper surface 102bu of the second hold region 102b, the structure prevents the source gas 200 from penetrating a clearance between the semiconductor wafer 70 and the semiconductor wafer holder 102C. The boundary between the source gas 200 and the purge gas 300 moves more upwardly so that the source gas 200 is diluted more efficiently with the purge gas 300 around the sidewall 70e. The dilution of the source gas 200 more firmly prevents an undesirable epitaxial film 71 from growing around on the sidewall 70e of the semiconductor wafer 70. The extended protrusion 102t prevents the semiconductor wafer 70 from being blown out of the semiconductor wafer holder 102C during the rotation of the semiconductor wafer holder 102C.

### Sixth Embodiment

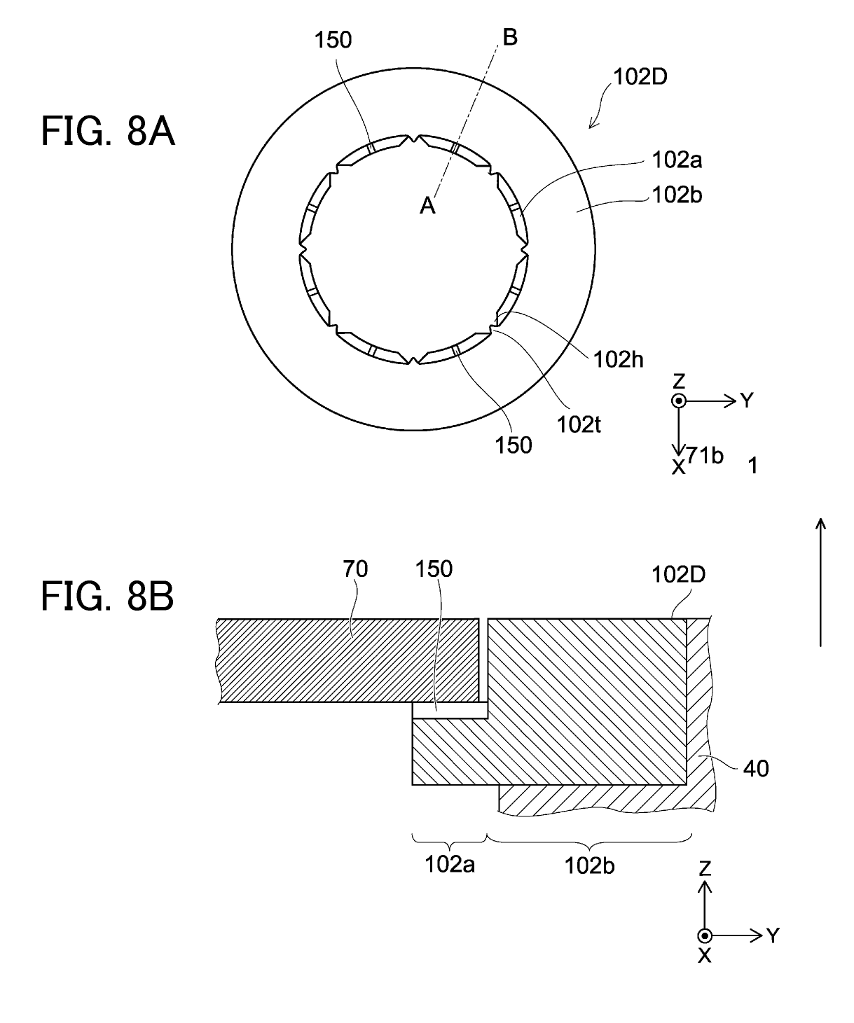

FIG. 8A is a schematic plan view showing a semiconductor wafer holder in accordance with a sixth embodiment. FIG. 8B is a schematic sectional view showing the semiconductor wafer holder in accordance with the sixth embodiment.

FIG. 8B shows a cross-section taken along the line A-B in FIG. 8A.

In the semiconductor wafer holder 102D in accordance with the sixth embodiment, the ring-like first hold region 102a has a plurality of convexes 150 locally in contact with a back of the semiconductor wafer 70. For example, the respective convexes 150 are arranged at even intervals on a circumference of the ring-like first hold region 102a. Positions of the convexes 150 are different from the positions of the ventholes 102h. For example, angular positions of the convexes 150 are different from the angular positions of the ventholes 102h in a rotation direction of the semiconductor wafer holder 102D.

The semiconductor wafer 70 is heated by radiation heat radiated from a heater 50 provided under the semiconductor wafer 70. The semiconductor wafer holder 102D is simultaneously heated with the heater 50. When the semiconductor wafer 70 is directly in contact with the first hold region 102a, the semiconductor wafer 70 can be unevenly heated by residual heat from the semiconductor wafer holder 102D.

In contrast, the convexes 150 are provided to the semiconductor wafer holder 102D in the sixth embodiment so that the semiconductor wafer 70 is held by the convexes 150 in the semiconductor wafer holder 102D. Thus, an outer circumference of the semiconductor wafer 70 is insusceptible to the residual heat from the semiconductor wafer holder 102D. As a result, in-plane temperature homogeneity in the semiconductor wafer 70 is enhanced during e growth. Alternatively, the convexes 150 or the like may be provided also to the above-described semiconductor wafer holders 101, 102A, 102B, and 102C.

### Seventh Embodiment

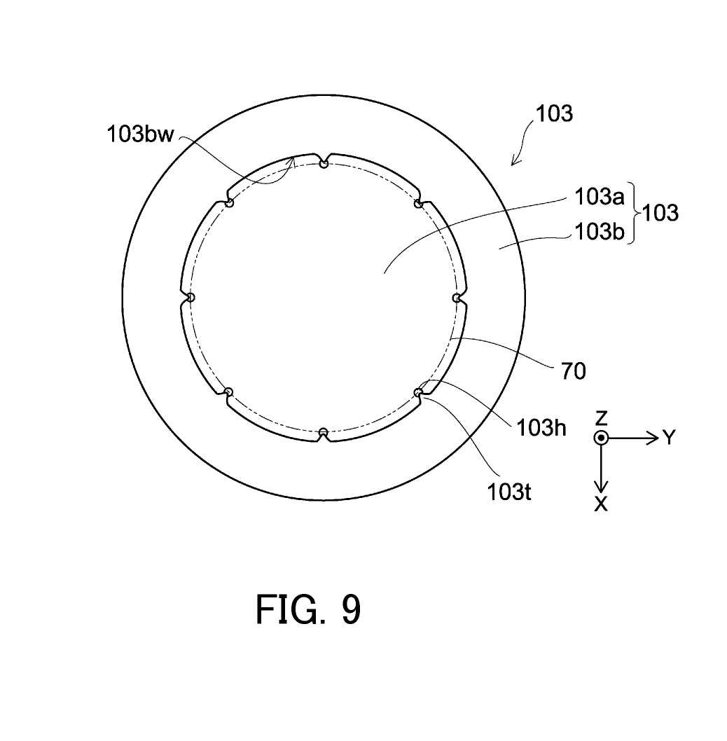

FIG. 9 is a schematic plan view showing a semiconductor wafer holder in accordance with a seventh embodiment.

The semiconductor wafer holder 103 in accordance with the seventh embodiment includes a first hold region 103a and a second hold region 103b. The first hold region 103a includes ventholes 103h. Protrusions 103t protrude from an inside surface 103bw of the second hold region 103b.

The first hold region 103a of the semiconductor wafer holder 103 is not through. The first hold region 103a of the semiconductor wafer holder 103 is not ring-like. The entire back of the semiconductor wafer 70 is held by the first hold region 103a. Such a semiconductor wafer holder 103 is also included in the embodiment.

A semiconductor layer will be formed on the semiconductor wafer 70 using one of the above-described semiconductor wafer holders.

Effects of the semiconductor wafer holders will be described.

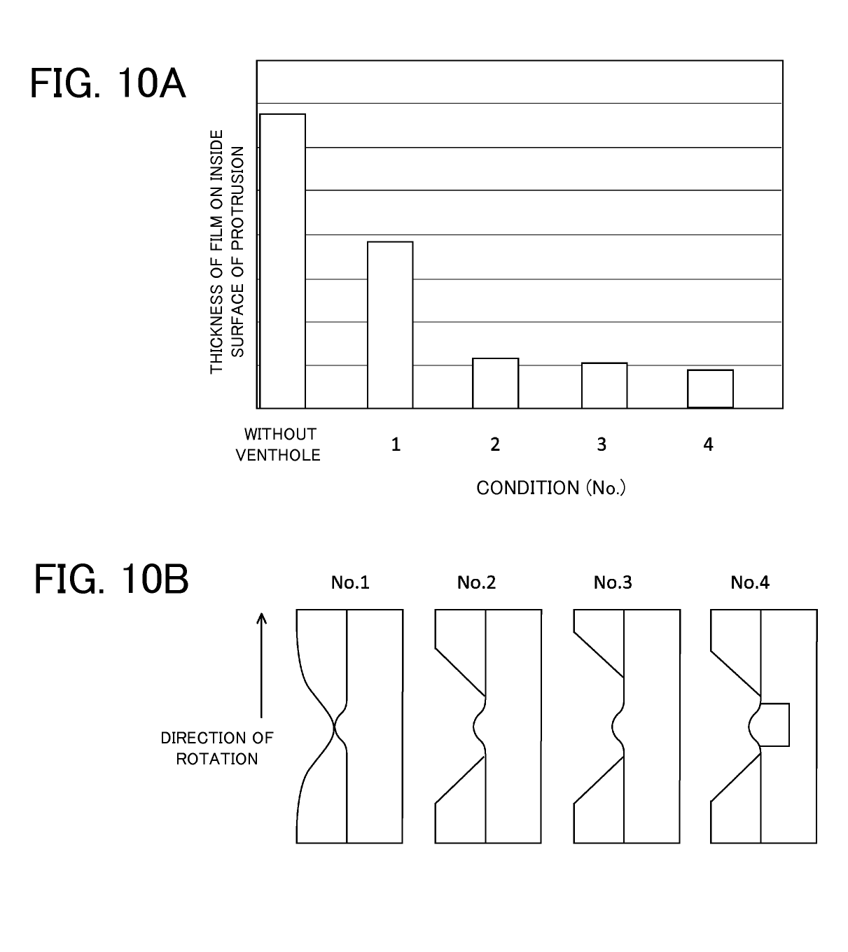

FIGS. 10A and 10B are diagrams showing the effects of the semiconductor wafer holders.

Planar shapes No. 1 and No. 2 correspond to the semiconductor wafer holder 102A. A planar area of the planar shape No. 2 is larger than that of the planar shape No. 1. The planar shape No. 3 corresponds to the semiconductor wafer holder 102B. The planar shape No. 4 corresponds to the semiconductor wafer holder 102C.

FIG. 10A shows a relation between thicknesses of epitaxial films 71 formed on the inside surface 102tw of the protrusion 102t and on the planar shapes No. 1 to No. 4. The thicknesses are shown in arbitrary units (a.u.). The result of FIG. 10A is derived by a simulation based on fluid analysis. A semiconductor wafer with a diameter of 200 mm is assumed for the simulation.

FIG. 10A reveals that the semiconductor wafer holder without a venthole yields a thickest epitaxial film. FIGS. 10A and 10B further reveal the following. A semiconductor wafer holder corresponding to the planar shape No. 1 is revealed to yield a first epitaxial film that is about half of the thickest film in thickness. A semiconductor wafer holder corresponding to the planar shape No. 2 has a larger venthole than the holder corresponding to the planar shape No. 1, and is revealed to yield a second epitaxial film that is thinner than the first epitaxial film.

A semiconductor wafer holder corresponding to the planar shape No. 3 has a venthole unsymmetrical to the center line of a protrusion, and is revealed to yield a third epitaxial film that is thinner than the second epitaxial film. A semiconductor wafer holder corresponding to the planar shape No. 4 has a protrusion that is extended above the level of the semiconductor wafer holder, and is revealed to yield a fourth epitaxial film that is thinner than the third epitaxial film. The fourth epitaxial film is the thinnest.

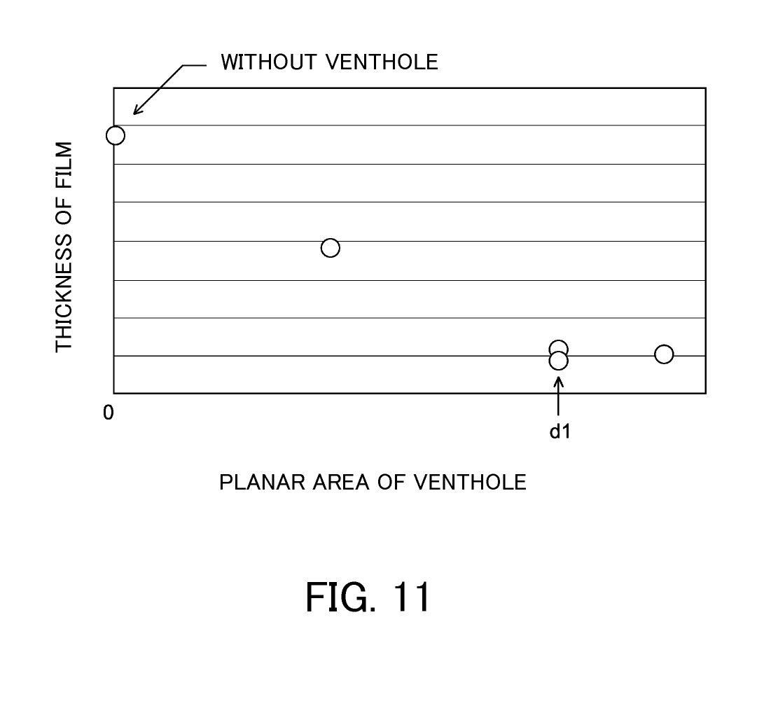

FIG. 11 is a schematic diagram showing effects of the semiconductor wafer holders.

In FIG. 11, the horizontal axis denotes the planar area of a venthole, and the vertical axis denotes the thicknesses of epitaxial films 71. FIG. 11 shows a relation between the planar areas and the thicknesses. The relation shown in FIG. 11 is derived by a simulation based on fluid analysis. The respective axes are expressed in arbitrary units (a.u.). The planar area is defined as the above-mentioned.

FIG. 11 reveals the following. A semiconductor wafer holder without a venthole yields a thickest film. As the planar area of a venthole increases, a film obtained becomes thinner. The film is the thinnest one at a predetermined planar area, e.g., dl. The specific value of dl is 9 mm², for example. It is therefore preferred that the planar area of the venthole is set to 9 mm² or larger in order to prevent an undesirable film growth around the sidewall 70e of the semiconductor wafer 70.

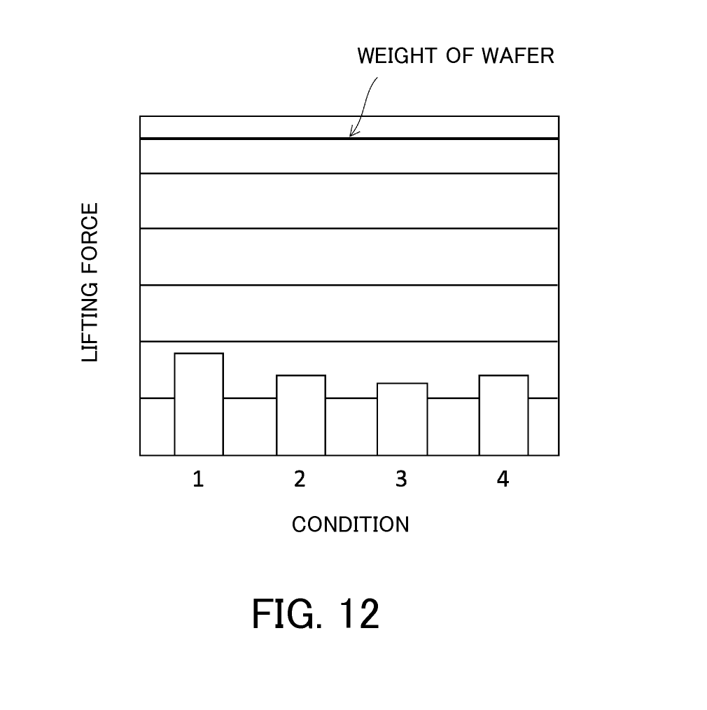

FIG. 12 is a schematic diagram showing effects of the semiconductor wafer holders.

FIG. 12 shows a relation between lifting force generated by a purge gas and the semiconductor wafer holders corresponding to the planar shapes No. 1 to No. 4. The relation shown in FIG. 12 is derived by a simulation based on fluid analysis. The lifting force is denoted in arbitrary units (a.u.). In the semiconductor manufacturing apparatus 1 of the embodiments, a purge gas is introduced through the purge-gas inlet 60 so as to give a pressure higher than the pressure of the process space 81 to the space 80, thereby causing the purge gas to flow out of the space 80 inside the rotation unit 40 through the ventholes and a source gas 200 around the sidewall 70e of the semiconductor wafer 70 to be diluted with the purge gas.

Increasing the flow rate of the purge gas can generate lifting force due to a difference between pressures of the space 80 and the space 81. The lifting force can blow the semiconductor wafer 70 from the semiconductor wafer holder.

FIG. 12 reveals that the lifting force of all the planar shapes No. 1 to No. 4 is equal to or below one third of the weight of the semiconductor wafer 70 or lower. FIG. 12 also reveals that the semiconductor wafer 70 is firmly held with the semiconductor wafer holder without being blown out of the semiconductor wafer holder.

In the semiconductor manufacturing apparatus 1 of the embodiments, the ventholes are provided near the protrusions of the semiconductor wafer holder so that a source gas is diluted with a purge gas, thereby preventing the semiconductor wafer from adhering to the semiconductor wafer holder and being blown out of the semiconductor wafer holder. Thus, the semiconductor manufacturing apparatus 1 enables fast film growth. As a result, the semiconductor manufacturing apparatus achieves high productivity and low manufacturing costs.

Although the semiconductor manufacturing apparatus of the embodiments has been described by taking silicon epitaxial growth as an example, the apparatus can be used for growth of other kinds of films.

While certain embodiments have been described, these embodiments have been presented by way of example only, and are not intended to limit the scope of the embodiments. Indeed, the novel embodiments described herein may be embodied in a variety of other forms; furthermore, various omissions, substitutions and changes in the form of the embodiments described herein may be made without departing from the spirit of the embodiments. The accompanying claims and their equivalents are intended to cover such forms or modifications as would fall within the scope and spirit of the embodiments.

Throughout the specification, a type of sentence describing that “a portion A is provided on a portion B” may include a sentence describing that “the portion A is provided above or over the portion B,” and vice versa. In other words, the sentence describing that “a portion A is provided on a portion B” may include not only a sentence describing that “the portion A is in contact with the portion B,” but also a sentence describing that “the portion A is not in contact with the portion B.”

Elements included in the above-described embodiments may be technically combined with each other. The combined elements are also included in the scope of the embodiments, as long as the combined elements include features of the embodiments. In the scope of the embodiments, one ordinarily skilled in the art will be able to conceive various omissions, substitutions and changes in the form of the embodiments. It may be recognized that the omissions, substitutions and changes will be also included in the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus, the apparatus comprising:
a chamber;
a reaction-gas inlet provided to the chamber, the inlet introducing a reaction gas into the chamber;
a gas exhaust port provided to the chamber, the port exhausting the reaction gas;
a rotation unit provided to the chamber;
a semiconductor wafer holder provided above the rotation unit, the holder holding a semiconductor wafer;
a heater provided inside the rotation unit; and
a purge-gas inlet to introduce a purge gas into a space, the space enclosed by the rotation unit, the semiconductor wafer holder and the semiconductor wafer,
the wafer holder including:
a first hold region to hold the semiconductor wafer, the first hold region having a plurality of ventholes provided to the first hold region so that the ventholes are just below a sidewall of the semiconductor wafer held by the first hold region; and
a second hold region held by the rotation unit, the second hold region surrounding the first hold region and having a protrusion provided above each of the ventholes such that the protrusion protrudes from the inside surface toward the first hold region to face the sidewall, wherein
a difference between levels of the first and second hold regions structurally include a first upper surface of the first hold region, a second upper surface of the second hold region, and an inside surface of the second hold region, the inside surface near the first and second upper surfaces.

2. The apparatus according to claim 1, wherein
the planar shape of the first hold region is ring-like; and
the ring-like first hold region holds an outer circumference of the semiconductor wafer.

3. The apparatus according to claim 2, wherein
the venthole is a cutout that is cut out from the inner circumference of the first hold region toward the outer circumference of the first hold region.

4. The apparatus according to claim 2, wherein
the first hold region has a plurality of convexes locally in contact with a back of the semiconductor wafer; and
the respective convexes are arranged at even intervals on a circumference of the first hold region.

5. The apparatus according to claim 4, wherein
positions of the convexes are different from the positions of the ventholes.

6. A semiconductor manufacturing apparatus, the apparatus comprising:
a chamber;
a reaction-gas inlet provided to the chamber, the inlet introducing a reaction gas into the chamber;
a gas exhaust port provided to the chamber, the port exhausting the reaction gas;
a rotation unit provided to the chamber;
a semiconductor wafer holder provided above the rotation unit, the holder holding a semiconductor wafer;
a heater provided inside the rotation unit; and
a purge-gas inlet to introduce a purge gas into a space, the space enclosed by the rotation unit, the semiconductor wafer holder and the semiconductor wafer,
the wafer holder including:
a first hold region to hold the semiconductor wafer, the first hold region having a plurality of ventholes provided to the first hold region so that the ventholes are just below a sidewall of the semiconductor wafer held by the first hold region; and
a second hold region held by the rotation unit, the second hold region surrounding the first hold region, wherein
the level of the first hold region and the levels of the second hold region differ.

7. The apparatus according to claim 6, wherein
the difference structurally includes a first upper surface of the first hold region, a second upper surface of the second hold region, and an inside surface of the second hold region; and
the second hold region has a protrusion provided above each of the ventholes such that the protrusion protrudes from the inside surface toward the first hold region to face the sidewall.

8. The apparatus according to claim 7, wherein
each of the ventholes has an unsymmetrical planar shape with respect to a center of the protrusion and is divided into a first venthole and a second venthole with respect to the center; and
the first venthole assigned to a rotation direction of the rotation unit has a larger planar shape than the second venthole assigned to an anti-rotation direction opposite to the rotation direction.

9. The apparatus according to claim 8, wherein
a level of an upper end of the protrusion is higher than the level of an upper end of the second hold region.

10. The apparatus according to claim 7, wherein
a level of an upper end of the protrusion is higher than the level of an upper end of the second hold region.

11. The apparatus according to claim 10, wherein
the planar shape of the first hold region is ring-like; and
the ring-like first hold region holds an outer circumference of the semiconductor wafer.

12. The apparatus according to claim 11, wherein
the venthole is a cutout that is cut out from the inner circumference of the first hold region toward the outer circumference of the first hold region.

13. The apparatus according to claim 6, wherein
each of the ventholes has an unsymmetrical planar shape with respect to a center of the protrusion and is divided into a first venthole and a second venthole with respect to the center; and
the first venthole assigned to a rotation direction of the rotation unit has a larger planar shape than the second venthole assigned to an anti-rotation direction opposite to the rotation direction.

14. The apparatus according to claim 13, wherein
the planar shape of the first hold region is ring-like; and
the ring-like first hold region holds an outer circumference of the semiconductor wafer.

15. The apparatus according to claim 14, wherein
the venthole is a cutout that is cut out from the inner circumference of the first hold region toward the outer circumference of the first hold region.

16. The apparatus according to claim 14, wherein
the first hold region has a plurality of convexes locally in contact with a back of the semiconductor wafer; and
the respective convexes are arranged at even intervals on a circumference of the first hold region.

17. The apparatus according to claim 1, wherein
the planar shape of the first hold region is ring-like; and
the ring-like first hold region holds an outer circumference of the semiconductor wafer.

18. The apparatus according to claim 17, wherein
the venthole is a cutout that is cut out from the inner circumference of the first hold region toward the outer circumference of the first hold region.

19. The apparatus according to claim 17, wherein
the first hold region has a plurality of convexes locally in contact with a back of the semiconductor wafer; and
the respective convexes are arranged at even intervals on a circumference of the first hold region.

20. A semiconductor wafer holder used for a semiconductor manufacturing apparatus, the holder comprising:
a first hold region to hold the semiconductor wafer, the first hold region having a plurality of ventholes provided to the first hold region so that the ventholes are just below a sidewall of the semiconductor wafer held by the first hold region; and
a second hold region held by the rotation unit, the second hold region surrounding the first hold region, wherein
the level of the first hold region and the levels of the second hold region differ.
